(19) United States
(12) Patent Application Publication
(10) Pub. No.: US 2023/0185151 A1
(43) Pub. Date: Jun. 15, 2023

(54) OPTICAL PATH CONTROL MEMBER AND DISPLAY DEVICE COMPRISING SAME

(71) Applicant: LG INNOTEK CO., LTD., Seoul (KR)

(72) Inventors: Mun Yeong SON, Seoul (KR); Byung Sook KIM, Seoul (KR); Jin Mi NOH, Seoul (KR)

(73) Assignee: LG INNOTEK CO., LTD., Seoul (KR)

(21) Appl. No.: 17/924,558

(22) PCT Filed: Apr. 19, 2021
(86) PCT No.: PCT/KR2021/004842

§ 371 Date: Nov. 10, 2022

(30) Foreign Application Priority Data
May 11, 2020 (KR) 10-2020-0056070

(51) Int. Cl. G02F 1/167; G02F 1/16757

(52) U.S. Cl. CPC G02F 1/167; G02F 1/16757; G02F 2001/1678

(57) ABSTRACT

An optical path control member according to an embodiment comprises: a first substrate; a first electrode disposed on the first substrate; an optical conversion part disposed on the first electrode; a second substrate disposed on the first substrate; a second electrode disposed below the second substrate; and an adhesive layer disposed between the optical conversion part and second electrode. The optical conversion part comprises partition parts and accommodation parts which are alternately disposed. The accommodation parts comprise a dispersion liquid and optical conversion particles. The light transmittance of the accommodation parts changes in accordance with the application of voltage, and the driving speed measured by 85% reach time is less than 6 seconds.

### TECHNICAL FIELD

An embodiment relates to an optical path control member, and to a display device including the same.

### BACKGROUND ART

A light blocking film blocks transmitting of light from a light source, and is attached to a front surface of a display panel which is a display device used for a mobile phone, a notebook, a tablet PC, a vehicle navigation device, a vehicle touch, etc., so that the light blocking film adjusts a viewing angle of light according to an incident angle of light to express a clear image quality at a viewing angle needed by a user when the display transmits a screen.

In addition, the light blocking film may be used for the window of a vehicle, building or the like to shield outside light partially to prevent glare, or to prevent the inside from being visible from the outside.

That is, the light blocking film may be an optical path control member that controls the movement path of light to block light in a specific direction and transmit light in a specific direction. Accordingly, it is possible to control the viewing angle of the user by controlling a transmission angle of the light by the light blocking film.

Meanwhile, such a light blocking film may be divided into a light blocking film that can always control the viewing angle regardless of the surrounding environment or the user’s environment and a switchable light blocking film that allow the user to turn on/off the viewing angle control according to the surrounding environment or the user’s environment.

Such a switchable light blocking film may be implemented by switching a pattern part to a light transmitting part and a light blocking part by filling the inside of the pattern part with particles that may move when a voltage is applied and a dispersion liquid for dispersing the particles and by dispersing and aggregating the particles.

When a content of optical conversion particles is lowered in order to improve a driving speed of the switchable light blocking film, the driving speed is improved, but there is a problem that the shielding performance is deteriorated.

In addition, the lower a height of a partition part used to prevent overflow of a filler, the better the driving speed, but there is a problem that the shielding performance is deteriorated. Meanwhile, as a partition pattern is formed, a front transmittance may be increased, but there is a problem that it is practically difficult to implement and the driving speed is lowered.

Therefore, an optical path control member having a new structure capable of solving the above problems is required.

### DISCLOSURE

### Technical Problem

An embodiment relates to an optical path control member with improved driving speed. In addition, the embodiment may provide an optical path control member with improved optical characteristics.

### Technical Solution

An optical path control member according to an embodiment includes: a first substrate; a first electrode disposed on the first substrate; an optical conversion part disposed on the first electrode; a second substrate disposed on the first substrate; a second electrode disposed under the second substrate; and an adhesive layer disposed between the optical conversion part and the second electrode, wherein the optical conversion part includes a partition part and an accommodation part alternately disposed, the accommodation part includes a dispersion liquid and optical conversion particles, the accommodation part has a light transmittance that changes according to application of voltage, and the dispersion liquid includes a solvent having a permittivity (ε) of 10 or less.

A display device according to an embodiment includes: a display panel; and the optical path control member disposed on the display panel, wherein the optical path control member includes: a first substrate; a first electrode disposed on the first substrate; an optical conversion part disposed on the first electrode; a second substrate disposed on the first substrate; a second electrode disposed under the second substrate; and an adhesive layer disposed between the optical conversion part and the second electrode, wherein the optical conversion part includes a partition part and an accommodation part alternately disposed, the accommodation part has a light transmittance that changes according to application of voltage, and the dispersion liquid includes a solvent having a permittivity (ε) of 10 or less.

### Advantageous Effects

In optical path control member according to an embodiment, a driving speed measured by 85% reach time may be less than 6 seconds.

In the embodiment, a solvent having a permittivity (ε) of 10 or less may be included as a dispersion liquid, thereby improving a driving speed and securing a chemical resistance and a side shielding rate.

Accordingly, the driving speed, optical characteristics, and durability of the optical path control member and a display device including the same may be improved.

### DESCRIPTION OF DRAWINGS

FIGS. 1 and 2 are perspective views of an optical path control member according to an embodiment.

FIGS. 3 and 4 are a perspective view of a first substrate and a first electrode and a perspective view of a second substrate and a second electrode of the optical path control member according to the embodiment.

FIG. 5 is a cross-sectional view taken along line A-A′ in FIG. 1.

FIGS. 6 to 9 are cross-sectional views taken along line A-A′ in FIG. 1 for describing shapes of various accommodation parts in the optical path control member according to the embodiment.

FIG. 10 is a photograph of an optical path control member according to Comparative Example.

FIG. 11 is a photograph of an optical path control member according to Comparative Example and Example.

FIGS. 12 to 18 are views for describing a method of manufacturing an optical path control member according to an embodiment.

FIGS. 19 and 20 are cross-sectional views of a display device to which an optical path control member according to an embodiment is applied.

FIGS. 21 to 23 are views for describing one embodiment of the display device to which the optical path control member according to the embodiment is applied.

### MODES OF THE INVENTION

Hereinafter, embodiments of the present invention will be described in detail with reference to the accompanying drawings. However, the spirit and scope of the present invention is not limited to a part of the embodiments described, and may be implemented in various other forms, and within the spirit and scope of the present invention, one or more of the elements of the embodiments may be selectively combined and replaced.

In addition, unless expressly otherwise defined and described, the terms used in the embodiments of the present invention (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art.

In addition, the terms used in the embodiments of the present invention are for describing the embodiments and are not intended to limit the present invention. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present invention, the terms such as first, second, A, B, (a), and (b) may be used. These terms are only used to distinguish the elements from other elements, and the terms are not limited to the essence, order, or order of the elements.

In addition, when an element is described as being “connected”, or “coupled” to another element, it may include not only when the element is directly “connected” to, or “coupled” to other elements, but also when the element is “connected”, or “coupled” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements.

Furthermore, when expressed as “on (over)” or “under (below)”, it may include not only the upper direction but also the lower direction based on one element.

Hereinafter, an optical path control member according to an embodiment will be described with reference to drawings. The optical path control member described below relates to a switchable optical path control member driven in various modes according to electrophoretic particles moving by application of a voltage.

Referring to FIGS. 1 to 4, an optical path control member 1000 according to an embodiment may include a first substrate 110, a second substrate 120, a first electrode 210, a second electrode 220, and an optical conversion part 300.

The first substrate 110 may support the first electrode 210. The first substrate 110 may be rigid or flexible.

In addition, the first substrate 110 may be transparent. For example, the first substrate 110 may include a transparent substrate capable of transmitting light.

The first substrate 110 may include glass, plastic, or a flexible polymer film. For example, the flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS), which is only an example, but the embodiment is not limited thereto.

In addition, the first substrate 110 may be a flexible substrate having flexible characteristics.

Further, the first substrate 110 may be a curved or bended substrate. That is, the optical path control member including the first substrate 110 may also be formed to have flexible, curved, or bent characteristics. Accordingly, the optical path control member according to the embodiment may be changed to various designs.

The first substrate 110 may extend in a first direction 1A, a second direction 2A, and a third direction 3A.

In detail, the first substrate 110 may include the first direction 1A corresponding to a length or width direction of the first substrate 110, a second direction 2A extending in a direction different from the first direction 1A and corresponding to the length or width direction of the first substrate 110, and a third direction 3A extending in a direction different from the first direction 1A and the second direction 2A and corresponding to a thickness direction of the first substrate 110.

For example, the first direction 1A may be defined as the length direction of the first substrate 110, the second direction 2A may be defined as the width direction of the first substrate 110 perpendicular to the first direction 1A, and the third direction 3A may be defined as the thickness direction of the first substrate 110. Alternatively, the first direction 1A may be defined as the width direction of the first substrate 110, the second direction 2A may be defined as the length direction of the first substrate 110 perpendicular to the first direction 1A, and the third direction 3A may be defined as the thickness direction of the first substrate 110.

Hereinafter, for convenience of description, the first direction 1A will be described as the length direction of the first substrate 110, the second direction 2A will be described as the width direction of the first substrate 110, and the third directions 3A will be described as the thickness direction of the first substrate 110.

The first electrode 210 may be disposed on one surface of the first substrate 110. In detail, the first electrode 210 may be disposed on an upper surface of the first substrate 110. That is, the first electrode 210 may be disposed between the first substrate 110 and the second substrate 120.

The first electrode 210 may include a transparent conductive material. For example, the first electrode 210 may include a conductive material having a light transmittance of about 80% or more. As an example, the first electrode 210 may include a metal oxide such as indium tin oxide, indium zinc oxide, copper oxide, tin oxide, zinc oxide, titanium oxide, etc.

The first electrode 210 may have a thickness of 0.05 µm to 2 µm.

Alternatively, the first electrode 210 may include various metals to realize low resistance. For example, the first electrode 210 may include at least one metal of chromium (Cr), nickel (Ni), copper (Cu), aluminum (Al), silver (Ag), molybdenum (Mo). Gold (Au), titanium (Ti), and alloys thereof.

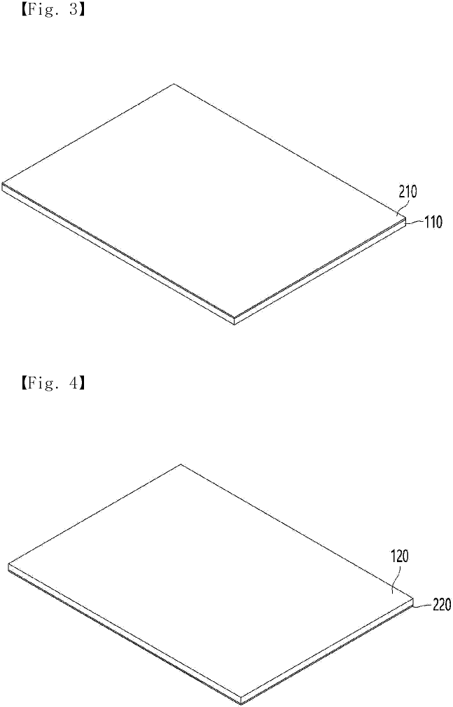

Referring to FIG. 3, the first electrode 210 may be disposed on the entire surface of one surface of the first substrate 110. In detail, the first electrode 210 may be disposed as a surface electrode on one surface of the first substrate 110. However, the embodiment is not limited thereto, and the first electrode 210 may be formed of a plurality of pattern electrodes having a uniform pattern such as a mesh or stripe shape.

For example, the first electrode 210 may include a plurality of conductive patterns. In detail, the first electrode 210 may include a plurality of mesh lines crossing each other and a plurality of mesh openings formed by the mesh lines.

Accordingly, even though the first electrode 210 includes a metal, the first electrode 210 is not visually recognized from the outside, so that visibility may be improved. In addition, the light transmittance is increased by the openings, so that the brightness of the optical path control member according to the embodiment may be improved.

The second substrate 120 may be disposed on the first substrate 110. In detail, the second substrate 120 may be disposed on the first electrode 210 on the first substrate 110.

The second substrate 120 may include a material capable of transmitting light. The second substrate 120 may include a transparent material. The second substrate 120 may include a material the same as or similar to that of the first substrate 110 described above.

For example, the second substrate 120 may include glass, plastic, or a flexible polymer film. For example, the flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS). This is only an example, but the embodiment is not limited thereto.

In addition, the second substrate 120 may be a flexible substrate having flexible characteristics.

Further, the second substrate 120 may be a curved or bended substrate. That is, the optical path control member including the second substrate 120 may also be formed to have flexible, curved, or bent characteristics. Accordingly, the optical path control member according to the embodiment may be changed to various designs.

The second substrate 120 may also extend in the first direction 1A, the second direction 2A, and the third direction 3A in the same manner as the first substrate 110 described above.

In detail, the second substrate 120 may include the first direction 1A corresponding to a length or width direction of the second substrate 120, the second direction 2A extending in a direction different from the first direction 1A and corresponding to the length or width direction of the second substrate 120, and the third direction 3A extending in the direction different from the first direction 1A and the second direction 2A and corresponding to the thickness direction of the second substrate 120.

For example, the first direction 1A may be defined as the length direction of the second substrate 120, the second direction 2A may be defined as the width direction of the second substrate 120 perpendicular to the first direction 1A, and the third direction 3A may be defined as the thickness direction of the second substrate 120.

Alternatively, the first direction 1A may be defined as the width direction of the second substrate 120, the second direction 2A may be defined as the length direction of the second substrate 120 perpendicular to the first direction 1A, and the third direction 3A may be defined as the thickness direction of the second substrate 120.

Hereinafter, for convenience of description, the first direction 1A will be described as the length direction of the second substrate 120, the second direction 2A the second direction 2A will be described as the width direction of the second substrate 120, and the third directions 3A will be described as the thickness direction of the second substrate 120.

The second electrode 220 may be disposed on one surface of the second substrate 120. In detail, the second electrode 220 may be disposed on a lower surface of the second substrate 120. That is, the second electrode 220 may be disposed on one surface of the second substrate 120 in which the second substrate 120 and the first substrate 110 face each other. That is, the second electrode 220 may be disposed to face the first electrode 210 on the first substrate 110. That is, the second electrode 220 may be disposed between the first electrode 210 and the second substrate 120.

The second electrode 220 may include a material the same as or similar to that of the first substrate 110 described above.

The second electrode 220 may include a transparent conductive material. For example, the second electrode 220 may include a conductive material having a light transmittance of about 80% or more. As an example, the second electrode 220 may include a metal oxide such as indium tin oxide, indium zinc oxide, copper oxide, tin oxide, zinc oxide, titanium oxide, etc.

The second electrode 220 may have a thickness of about 0.1 µm to about 0.5 µm.

Alternatively, the second electrode 220 may include various metals to realize low resistance. For example, the second electrode 220 may include at least one metal of chromium (Cr), nickel (Ni), copper (Cu), aluminum (Al), silver (Ag), molybdenum (Mo). gold (Au), titanium (Ti), and alloys thereof.

Referring to FIG. 4, the second electrode 220 may be disposed on the entire surface of one surface of the second substrate 120. In detail, the second electrode 220 may be disposed as a surface electrode on one surface of the second substrate 120. However, the embodiment is not limited thereto, and the second electrode 220 may be formed of a plurality of pattern electrodes having a uniform pattern such as a mesh or stripe shape.

For example, the second electrode 220 may include a plurality of conductive patterns. In detail, the second electrode 220 may include a plurality of mesh lines crossing each other and a plurality of mesh openings formed by the mesh lines.

Accordingly, even though the second electrode 220 includes a metal, the second electrode 220 is not visually recognized from the outside, so that visibility may be improved. In addition, the light transmittance is increased by the openings, so that the brightness of the optical path control member according to the embodiment may be improved.

The first substrate 110 and the second substrate 120 may have sizes corresponding to each other. The first substrate 110 and the second substrate 120 may have sizes the same as or similar to each other.

In detail, a first length extending in the first direction 1A of the first substrate 110 may have a size the same as or similar to a second length L2 extending in the first direction 1A of the second substrate 120.

For example, the first length and the second length may have a size of 300 mm to 400 mm.

In addition, a first width extending in the second direction 2A of the first substrate 110 may have a size the same as or similar to a second width extending in the second direction 2A of the second substrate 120.

For example, the first width and the second width may have a size of 150 mm to 200 mm.

In addition, a first thickness extending in the third direction 3A of the first substrate 110 may have a size the same as or similar to a second thickness extending in the third direction 3A of the second substrate 120.

For example, the first thickness and the second thickness may have a size of 30 µm to 200 µm.

Referring to FIG. 1, the first substrate 110 and the second substrate 120 may be disposed to be misaligned from each other.

In detail, the first substrate 110 and the second substrate 120 may be disposed at positions misaligned from each other in the first direction 1A. In detail, the first substrate 110 and the second substrate 120 may be disposed so that side surfaces of the substrates are misaligned from each other.

Accordingly, the first substrate 110 may be disposed to protrude in one direction in the first direction 1A, and the second substrate 120 may be disposed to protrude in the other direction in the second direction 2A.

That is, the first substrate 110 may include a first protrusion protruding in one direction in the first direction 1A, and the second substrate 110 may include a second protrusion protruding in the other direction in the first direction 1A.

Accordingly, the optical path control member 1000 may include a region where the first electrode 210 is exposed on the first substrate 110 and a region where the second electrode 220 is exposed under the second substrate 120.

That is, the first electrode 210 disposed on the first substrate 110 may be exposed at the first protrusion, and the second electrode 220 disposed under the second substrate 120 may be exposed at the second protrusion.

The first electrode 210 and the second electrode 220 exposed at the protrusions may be connected to an external printed circuit board through a connection portion that will be described below.

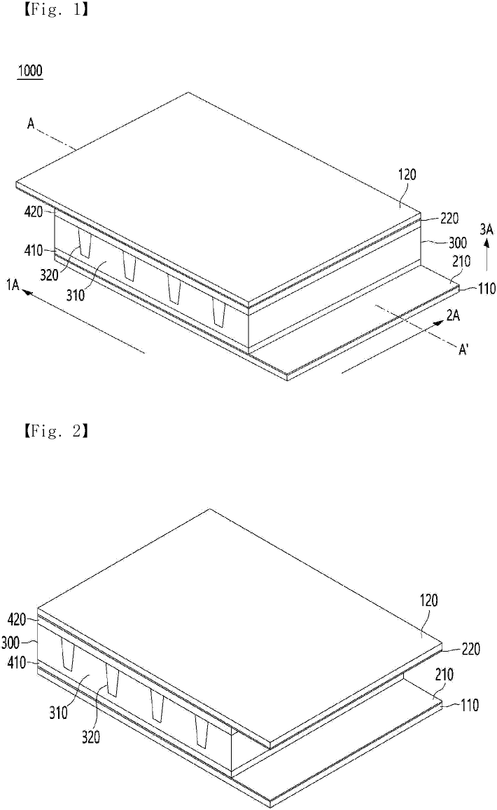

Alternatively, referring to FIG. 2, the first substrate 110 and the second substrate 120 may be disposed at positions corresponding to each other. In detail, the first substrate 110 and the second substrate 120 may be disposed so that each side surface corresponds to each other.

Accordingly, the first substrate 110 may be disposed to protrude in one direction of the first direction 1A, and the second substrate 120 may also be disposed to protrude in one direction of the first direction 1A, that is, in the same direction as the first substrate 110.

That is, the first substrate 110 may include the first protrusion protruding in one direction in the first direction 1A, and the second substrate may also include the second protrusion protruding in one direction in the first direction 1A.

That is, the first protrusion and the second protrusion may protrude in the same direction.

Accordingly, the optical path control member 1000 may include the region where the first electrode 210 is exposed on the first substrate 110 and the region where the second electrode 220 is exposed under the second substrate 120.

That is, the first electrode 210 disposed on the first substrate 110 may be exposed at the first protrusion, and the second electrode 220 disposed under the second substrate 120 may be exposed at the second protrusion.

The first electrode 210 and the second electrode 220 exposed at the protrusions may be connected to the external printed circuit board through the connection portion that will be described below.

The optical conversion part 300 may be disposed between the first substrate 110 and the second substrate 120. In detail, the optical conversion part 300 may be disposed between the first electrode 210 and the second electrode 220.

An adhesive layer or a buffer layer may be disposed between at least one of between the optical conversion part 300 and the first substrate 110 or between the optical conversion part 300 and the second substrate 120, and the first substrate 110, the second substrate 120, and the optical conversion part 300 may be adhered to each other by the adhesive layer and/or the buffer layer.

The optical conversion part 300 may include a plurality of partition parts and accommodation parts. Optical conversion particles that move according to application of a voltage may be disposed in the accommodation part, and light transmission characteristics of the optical path control member may be changed by the optical conversion particles.

A size of the optical conversion part 300 may be smaller than a size of at least one of the first substrate 110 and the second substrate 120.

In detail, a length of the optical conversion part 300 in the first direction may be smaller than a length of at least one of the first substrate 110 and the second substrate 120 in the first direction.

In addition, a width of the optical conversion part 300 in the second direction may be the same as or smaller than a width of at least one of the first substrate 110 and the second substrate 120 in the second direction.

In addition, at least one of both ends of the first substrate 110 and the second substrate 120 in the first direction may be disposed outside both ends of the optical conversion part 300 in the first direction.

Accordingly, a sealing part (not shown in the drawing) may be easily disposed, and adhesive properties of the sealing part may be improved.

An improvement in adhesive properties of the optical path control member according to the embodiment will be described with reference to FIG. 5.

The optical path control member according to the embodiment may include an optical conversion material. For example, the optical conversion material 320′ may be an EPD ink. In order to accommodate the optical conversion material 320′ and prevent overflow thereof, the optical conversion part 300 may be used. The optical conversion part 300 may include an accommodation part 320 for accommodating the optical conversion material 320′ and a partition part 310 for preventing the optical conversion material 320′ from overflowing.

The optical conversion part 300 may be formed of a photocurable resin. For example, the optical conversion part 300 may be formed by imprinting the photocurable resin. That is, the partition part 310 and the accommodation part 320 may be formed of the photocurable resin.

In detail, the partition part 310 may include a resin material. For example, the partition part 310 may include a photocurable resin material. As an example, the partition part 310 may include a urethane resin or the like.

The photocurable resin may include urethane acrylate, an acrylate monomer, isobomyl acrylate, an additive, a photoinitiator, and acryloylmorpholine. For example, the photoinitiator may include 1-Hydroxycyclohexyl Phenylmethanone.

The photocurable resin may include an oligomer, a monomer, a photopolymerization initiator, and an additive. The photocurable resin may form the optical conversion part by reaction of a polymer-type prepolymer, a polyfunctional monomer as a diluent, and a photopolymerization initiator.

Here, the additive may be various materials added to improve the driving speed of a device. For example, the additive may be a material that may be applied to the photocurable resin to increase the driving speed of the EPD ink. Here, the additive may refer to various materials for improving releasability or electrical characteristics of the photocurable resin. For example, the additive may refer to various materials including a release additive and/or an antistatic agent.

Details of the optical conversion part 300 will be described in detail below.

Referring to FIGS. 5 to 9, the optical conversion part 300 may include a partition part 310, and an accommodation part 320.

The partition part 310 may be defined as a partition part dividing the accommodation part. That is, the partition part 310 may transmit light as a barrier region dividing a plurality of accommodation parts. In addition, the accommodation part 320 may be defined as a variable region where the accommodation part 320 is switched to a light blocking part and a light transmitting part according to application of a voltage.

The partition part 310 and the accommodation part 320 may be alternately disposed with each other. The partition part 310 and the accommodation part 320 may be disposed to have different widths. For example, a width of the partition part 310 may be greater than that of the accommodation part 320.

The partition part 310 and the accommodation part 320 may be alternately disposed with each other. In detail, the partition part 310 and the accommodation part 320 may be alternately disposed with each other. That is, each of the partition parts 310 may be disposed between the accommodation parts 320 adjacent to each other, and each of the accommodation parts 320 may be disposed between the adjacent partition parts 310.

The partition part 310 may include a transparent material. The partition part 310 may include a material that may transmit light.

The partition part 310 may transmit light incident on any one of the first substrate 110 and the second substrate 120 toward another substrate.

For example, in FIGS. 6 and 9, light may be emitted from the second substrate 120 by a light source disposed on the second substrate 120, and the light may be incident on the first substrate 110. In this case, the partition part 310 may transmit the light, and the transmitted light may move toward the first substrate 110.

The accommodation part 320 may include the dispersion liquid 320a and the optical conversion particles 320b. In detail, the accommodation part 320 may be filled by injecting the dispersion liquid 320a. A plurality of optical conversion particles 320b may be dispersed in the dispersion liquid 320a.

The dispersion liquid 320a may be a material for dispersing the optical conversion particles 320b. The dispersion liquid 320a may include a transparent material. The dispersion liquid 320a may include a non-polar solvent. In addition, the dispersion liquid 320a may include a material capable of transmitting light.

The optical conversion particles 320b may be disposed to be dispersed in the dispersion liquid 320a. In detail, the plurality of optical conversion particles 320b may be disposed to be spaced apart from each other in the dispersion liquid 320a.

The optical conversion particles 320b may include a material capable of absorbing light. That is, the optical conversion particles 320b may be light absorbing particles. The optical conversion particles 320b may have a color. For example, the optical conversion particles 320b may have a black-based color. As an example, the optical conversion particles 320b may include carbon black.

The optical conversion particles 320b may have a polarity by charging a surface thereof. For example, the surface of the optical conversion particles 320b may be charged with a negative (-) charge. Accordingly, according to the application of the voltage, the optical conversion particles 320b may move toward the first electrode 210 or the second electrode 220.

The light transmittance of the accommodation part 320 may be changed by the optical conversion particles 320b. In detail, the accommodation part 320 may be switched to the light blocking part and the light transmitting part by changing the light transmittance due to the movement of the optical conversion particles 320b. That is, the accommodation part 320 may change the transmittance of light passing through the accommodation part 320 by dispersion and aggregation of the optical conversion particles 320b disposed inside the dispersion liquid 320a.

For example, the optical path control member according to the embodiment may be converted from a first mode to a second mode or from the second mode to the first mode by a voltage applied to the first electrode 210 and the second electrode 220.

In detail, in the optical path control member according to the embodiment, the accommodation part 320 becomes the light blocking part in the first mode, and light of a specific angle may be blocked by the accommodation part 320. That is, a viewing angle of the user viewing from the outside is narrowed, so that the optical path control member may be driven in a privacy mode.

In addition, in the optical path control member according to the embodiment, the accommodation part 320 becomes the light transmitting part in the second mode, and in the optical path control member according to the embodiment, light may be transmitted through both the partition part 310 and the accommodation part 320. That is, the viewing angle of the user viewing from the outside may be widened, so that the optical path control member may be driven in a share mode.

Switching from the first mode to the second mode, that is, the conversion of the accommodation part 320 from the light blocking part to the light transmitting part may be realized by movement of the optical conversion particles 320b of the accommodation part 320. That is, the optical conversion particles 320b may have a charge on the surface thereof and may move toward the first electrode or the second electrode according to the application of a voltage according to characteristics of the charge. That is, the optical conversion particles 320b may be electrophoretic particles

In detail, the accommodation part 320 may be electrically connected to the first electrode 210 and the second electrode 220.

In this case, when a voltage is not applied to the optical path control member from the outside, the optical conversion particles 320b of the accommodation part 320 are uniformly dispersed in the dispersion liquid 320a, and the accommodation part 320 may block light by the optical conversion particles. Accordingly, in the first mode, the accommodation part 320 may be driven as the light blocking part.

Alternatively, when a voltage is applied to the optical path control member from the outside, the optical conversion particles 320b may move. For example, the optical conversion particles 320b may move toward one end or the other end of the accommodation part 320 by a voltage transmitted through the first electrode 210 and the second electrode 220. That is, the optical conversion particles 320b may move from the accommodation part 320 toward the first electrode 210 or the second electrode 220.

In detail, when a voltage is applied to the first electrode 210 and/or the second electrode 220, an electric field is formed between the first electrode 210 and the second electrode 220, and the optical conversion particles 320b charged with the negative charge may move toward a positive electrode of the first electrode 210 and the second electrode 220 using the dispersion liquid 320a as a medium.

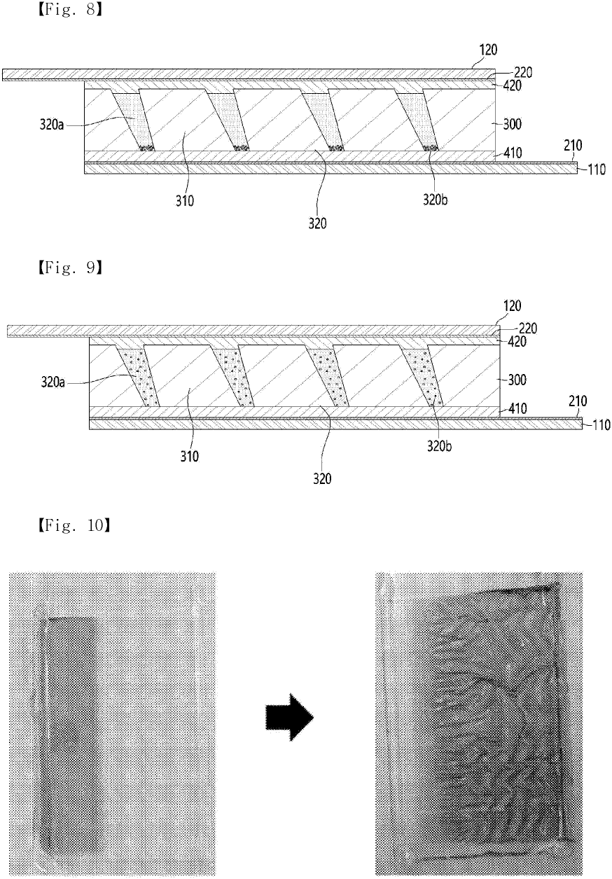

That is, when the voltage is applied to the first electrode 210 and/or the second electrode 220, as shown in FIG. 8, the optical conversion particles 320b may move toward the first electrode 210 in the dispersion liquid 320a. That is, the optical conversion particles 320b may move in one direction, and the accommodation part 320 may be driven as the light transmitting part.

Alternatively, when the voltage is not applied to the first electrode 210 and/or the second electrode 220, as shown in FIG. 9, the optical conversion particles 320b may be uniformly dispersed in the dispersion liquid 320a to drive the accommodation part 320 as the light blocking part.

Accordingly, the optical path control member according to the embodiment may be driven in two modes according to a user’s surrounding environment. That is, when the user requires light transmission only at a specific viewing angle, the accommodation part is driven as the light blocking part, or in an environment in which the user requires high brightness, a voltage may be applied to drive the accommodation part as the light transmitting part.

Therefore, since the optical path control member according to the embodiment may be implemented in two modes according to the user’s requirement, the optical path control member may be applied regardless of the user’s environment.

Meanwhile, the accommodation part may be disposed in a different shape in consideration of driving characteristics and the like.

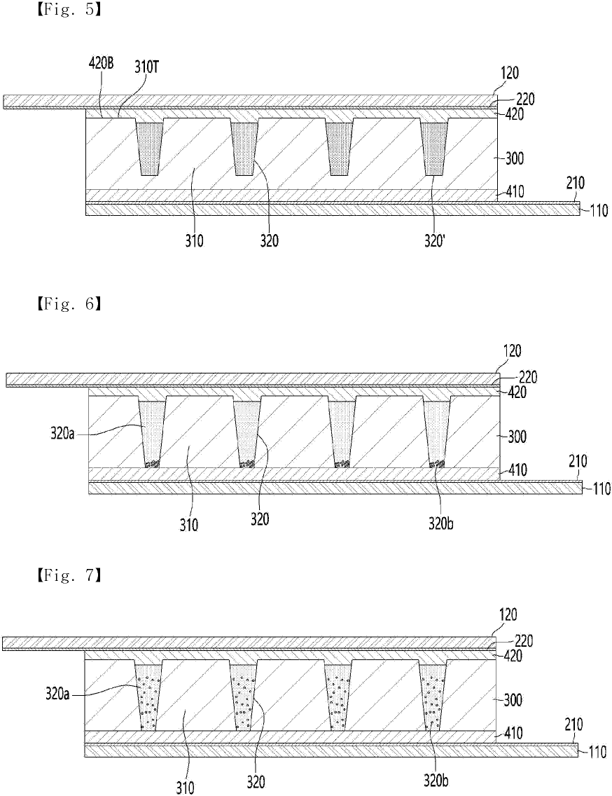

Referring to FIGS. 6 and 7, in an optical path control member according to another embodiment, both ends of an accommodation part 320 may be disposed in contact with a buffer layer 410 and an adhesive layer 420 unlike FIG. 5.

For example, a lower portion of the accommodation part 320 may be disposed in contact with the buffer layer 410, and an upper portion of the accommodation part 320 may be disposed in contact with the adhesive layer 420.

Accordingly, a distance between the accommodation part 320 and the first electrode 210 may be reduced, so that the voltage applied from the first electrode 210 may be smoothly transmitted to the accommodation part 320.

Accordingly, a moving speed of the optical conversion particles 320b inside the accommodation part 320 may be improved, and thus the driving characteristics of the optical path control member may be improved.

In addition, referring to FIGS. 8 and 9, in an optical path control member according to an embodiment, unlike FIGS. 6 and 7, an accommodation part 320 may be disposed to have a constant inclination angle θ.

In detail, referring to FIGS. 8 and 9, the accommodation part 320 may be disposed to have an inclination angle θ of greater than 0° to less than 90° with respect to the first substrate 110. In detail, the accommodation part 320 may extend upward while having an inclination angle θ of greater than 0° to less than 90° with respect to one surface of the first substrate 110.

Accordingly, when the optical path control member is used together with a display panel, moire caused by an overlapping phenomenon between a pattern of the display panel and the accommodation part 320 of the optical path control member may be alleviated, thereby improving user visibility.

Examples and Comparative Examples will be described in detail with reference to FIGS. 10 to 13.

In order to improve a driving speed of an EPD device, various attempts may be considered.

In order to improve the driving speed of the EPD device, a height of the partition part may be lowered, but there is a problem that the shielding performance is deteriorated. Meanwhile, in order to improve the driving speed of the EPD device, the content of the optical conversion particles 320b may be lowered, but there is a problem that the shielding performance is deteriorated.

Therefore, in order to improve the driving speed of the EPD device, an attempt to increase a permittivity (ε) of a solvent may be considered.

That is, when the permittivity (ε) of the solvent is increased, an electron mobility (µ) is increased, so that the driving speed may be improved.

With reference to FIG. 10, a change over time of an optical path control member manufactured using a solvent having a high permittivity will be described.

FIG. 10 is a photograph showing a change in appearance of an optical path control member manufactured using a polar solvent having a high permittivity over time.

In detail, when γ-Butyrolactone is used as a solvent, it can be confirmed that the appearance is changed by reaction between the solvent and the adhesive layer and/or the solvent and the optical conversion part.

In Comparative Example of FIG. 10, it can be confirmed that there is a problem in chemical resistance due to swelling of a resin layer of the optical conversion part. In addition, it can be confirmed that the optical path control member manufactured using the polar solvent having the high permittivity has a problem that the side shielding rate is lowered.

That is, the driving speed may be increased by using the solvent having the high permittivity as the dispersion liquid, but it can be confirmed that there is a possibility of a trade-off relationship such as a problem of a decrease in chemical resistance with surrounding materials and a decrease in the side shielding rate.

Therefore, there is a need for a solvent that may satisfy all of the driving speed, the chemical resistance, and the side shielding rate while maintaining an appropriate level of permittivity.

In order to solve such a problem, as a result of various attempts, the dispersion liquid 320a of Example 1 may include a solvent having a permittivity (ε) of 10 or less. In detail, the dispersion liquid 320a may include a solvent having a permittivity (ε) of 5 or less. In more detail, the dispersion liquid 320a may include a solvent having a permittivity (ε) of 3 or less. In more detail, the dispersion liquid 320a may include a solvent having a permittivity (ε) greater than 2.1 and 3 or less.

Here, the high dielectric solvent may refer to a solvent having a permittivity (ε) of 10 or less. In detail, the high dielectric solvent may refer to a solvent having a permittivity (ε) of 5 or less. In more detail, the high dielectric solvent may refer to a solvent having a permittivity (ε) of 3 or less. As such, when the high dielectric solvent having a permittivity (ε) of 10 or less is used, it may exhibit an effect of increasing the driving speed of the optical path control member and the display device including the same without the change in appearance. When a solvent having a permittivity (ε) of greater than 10 is used, it can be confirmed that the appearance is changed by reaction between the solvent and the adhesive layer and/or the solvent and the optical conversion part. In detail, when the solvent having the permittivity (ε) greater than 10 is used, a problem in chemical resistance may occur due to a swelling phenomenon of the resin layer of the optical conversion part. In addition, when the solvent having the permittivity (ε) greater than 10 is used, a problem that the side shielding rate of the optical path control member is lowered may occur.

In Example, a polar solvent may be used alone in order to adjust the permittivity of the dispersion liquid 320a to an appropriate level. The polar solvent may refer to a solvent having a permittivity of 10 or less. For example, the polar solvent may refer to a solvent having an oil-based permittivity of 10 or less, such as di-(propylene glycol) butyl ether, and a mixture of isomers thereof, γ-Butyrolactone, MS5000, dimethyl 2-methylpentanedioate, liquid crystal, and the like.

Alternatively, in Example, a polar solvent may be mixed with a low permittivity solvent to adjust the permittivity of the dispersion liquid 320a to an appropriate level. Here, as a method of mixing the solvent, various methods including hand shaking, stirring using a magnetic bar, vortexing, ball milling, and the like may be used.

The dispersion liquid 320a may include one or more solvents.

The dispersion liquid 320a may include a polar solvent. The polar solvent may refer to a solvent having a dielectric constant of 10 or less.

The dispersion liquid 320a may include a non-polar solvent. For example, the dispersion liquid 320a may include a hydrocarbon fluid. For example, the dispersion liquid 320a may include Isopar M.

The dispersion liquid 320a may include a mixture of solvents having mutually different permittivity. For example, a solvent in which Isopar M and propylene glycol phenyl ether are mixed may be used as the dispersion liquid 320a. For example, the dispersion liquid 320a may be a mixture of Isopar M and 1-heptanol. For example, the dispersion liquid 320a may be a solvent in which Isopar M and liquid crystal are mixed. Of course, the dispersion liquid in Example is not limited thereto and may include mixed solutions of various combinations.

With reference to FIG. 11 and Table 1, experimental results according to a range of the permittivity will be described.

When the permittivity (ε) of the dispersion liquid is greater than 10, the dispersion liquid may react with the resin layer or adhesive layer constituting the optical conversion part. In addition, when the permittivity (ε) of the dispersion liquid is greater than 10, a phenomenon of agglomeration of particles may appear due to a high polarity of the solvent.

When the permittivity (ε) of the dispersion is 2.1 or less, the driving speed may be slow.

When the dispersion liquid includes a solvent having a permittivity (ε) of 10 or less, it can be confirmed that the share mode and the privacy mode are quickly switched and there is no change in appearance.

Hereinafter, the experimental results of Comparative Examples and Examples will be described with reference to Table 1.

TABLE 1

| | | | | | | |
|---|---|---|---|---|---|---|
| Category | Example 1 | Example 2 | Example 3 | Example 4 | Comparative Example 1 | Comparative Example 2 |
| Permittivity | 3.0 | 3.8 | 3.8 | 10.0 | 2.1 | 11.1 |
| Privacy side luminance | 3.6% | 3.6% | 3.7% | 3.8% | 3.4% | 3.8% |
| 85% reach time | 4.6 sec | 4.5 sec | 4.5sex | 4.4 sec | 7.3 sec | 4.4 sec |
| Change in appearance | No | No | No | No | No | Yes |

In Table 1, Examples 1, 2, and 4 are obtained by mixing a low permittivity solvent with MS 5000 which is a high permittivity solvent. Here, the low permittivity solvent and the high permittivity solvent MS 5000 were mixed through vortexing. In Table 1, Example 3 is a mixture of liquid crystal which is a high permittivity solvent with a low permittivity solvent. Here, liquid crystal which is the high permittivity solvent is mixed with a low permittivity solvent through vortexing.

The 85% reach time may refer to a time taken to reach (maximum luminance -minimum luminance)*0.85.

In the results of Table 1, in Example, it can be confirmed that the driving speed measured by the 85% reach time is less than 6 seconds. In detail, in Examples 1 to 4, it can be confirmed that the driving speed measured by the 85% reach time is less than 5 seconds. Through the measurement of the 85% reach time, it can be confirmed that as the permittivity of the solvent increases, the driving speed of the optical path control member and the display device including the same is fast.

In addition, in Example using the solvent having a permittivity (ε) of 10 or less, it can be confirmed that the solvent does not react with the optical conversion part and/or the adhesive layer, and thus chemical resistance may be secured.

In addition, it can be confirmed that the side shielding rate is secured in Example using the solvent having a permittivity (ε) of 10 or less.

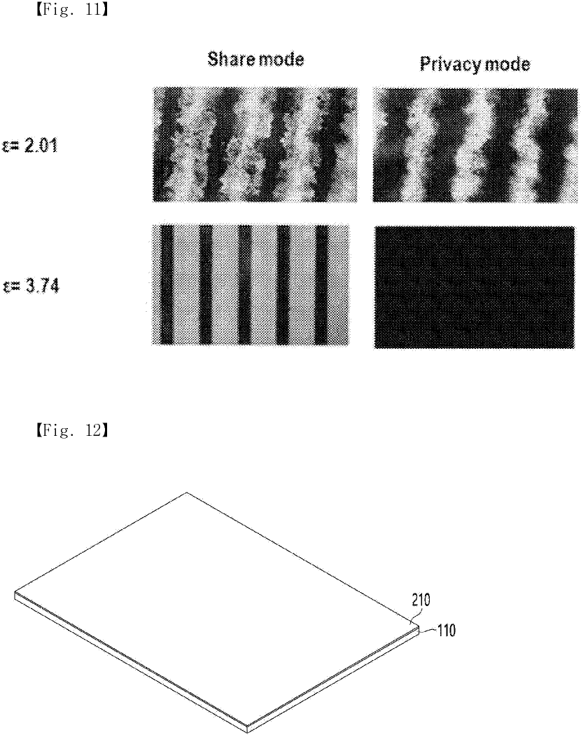

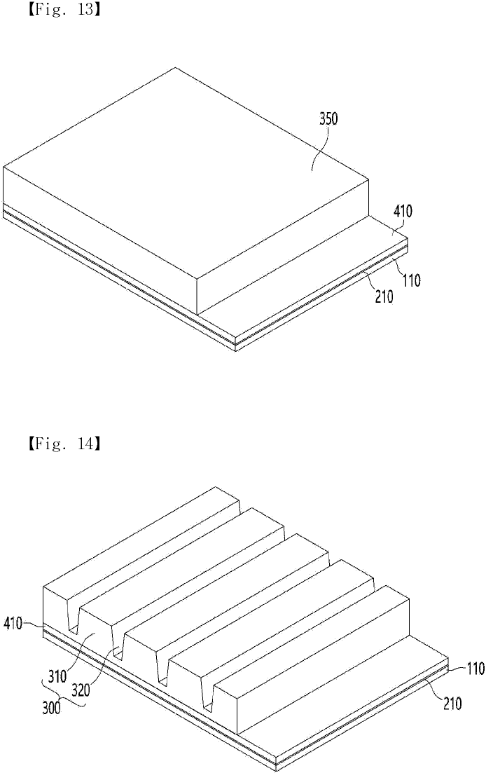

Hereinafter, a method of manufacturing an optical path control member according to an embodiment will be described with reference to FIGS. 12 to 18.

Referring to FIG. 12, a first substrate 110 and an electrode material for forming a first electrode are prepared. Then, the first electrode may be formed by coating or depositing the electrode material on one surface of the first substrate. In detail, the electrode material may be formed on the entire surface of the first substrate 110. Accordingly, the first electrode 210 formed as a surface electrode may be formed on the first substrate 110.

Subsequently, referring to FIG. 13, a resin layer 350 may be formed by coating a resin material on the first electrode 210. In detail, the resin layer 350 may be formed by applying a urethane resin or an acrylic resin on the first electrode 210.

In this case, before disposing the resin layer 350, a buffer layer 410 may be additionally disposed on the first electrode 210. In detail, by disposing the resin layer 350 on the buffer layer 410 after disposing the buffer layer 410 having good adhesion to the resin layer 350 on the first electrode 210, it is possible to improve the adhesion of the resin layer 350.

For example, the buffer layer 410 may include an organic material including a lipophilic group such as —CH—, an alkyl group, etc. Having good adhesion to the electrode and a hydrophilic group such as —NH, —OH, —COOH, etc. Having a good adhesion to the resin layer 410.

The resin layer 350 may be disposed on a partial region of the first substrate 110. That is, the resin layer 350 may be disposed in an area smaller than that of the first substrate 110. Accordingly, a region where the resin layer 350 is not disposed and the first electrode 210 is exposed may be formed on the first substrate 110. In addition, when the buffer layer 410 is disposed on the first electrode 210, a region where the buffer layer 410 is exposed may be formed.

In detail, a size of a third length extending in the first direction of the resin layer 350 may be less than a size of a first length extending in the first direction of the first substrate 110, and a size of a third width extending in the second direction may be less than or equal to a size of a first width extending in the second direction of the first substrate 110.

That is, a length of the resin layer 350 may be smaller than a length of the first substrate 110, and a width of the resin layer 350 may be equal to or smaller than a width of the first substrate 110.

Subsequently, referring to FIG. 14, the resin layer 350 may be patterned to form a plurality of partition parts 310 and a plurality of accommodation parts 320 in the resin layer 350. In detail, an engraved portion may be formed in the resin layer 350 to form an engrave-shaped accommodation part 320 and the emboss-shaped partition part 310 between the engraved portions.

Accordingly, an optical conversion part 300 including the partition part 310 and the accommodation part 320 may be formed on the first substrate 110.

In addition, the buffer layer 410 exposed on the first electrode 210 may be removed to expose the first electrode 210 in a region where the first substrate 110 protrudes.

Subsequently, referring to FIG. 15, a second electrode and an electrode material for forming a second substrate 120 and are prepared. Then, the second electrode may be formed by coating or depositing the electrode material on one surface of the second substrate. In detail, the electrode material may be formed on the entire surface of the second substrate 120. Accordingly, the second electrode 220 formed as a surface electrode may be formed on the second substrate 120.

A size of the second substrate 120 may be smaller than that of the first substrate 110. In addition, the size of the second substrate 120 may be smaller than that of the resin layer 350.

In detail, a size of a second length extending in a first direction of the second substrate 120 may be greater than the third length extending in the first direction of the resin layer 350, and a size of a second width extending in a second direction of the second substrate 120 may be smaller than the size of the third width extending in the second direction of the resin layer 350.

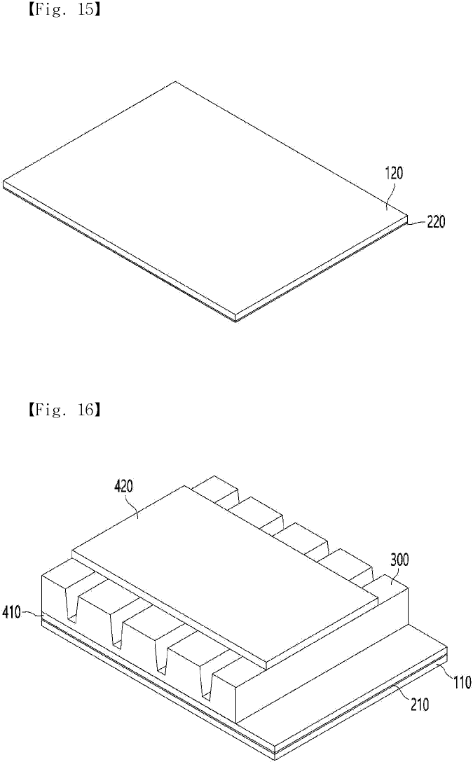

Subsequently, referring to FIG. 16, an adhesive layer 420 may be formed by coating an adhesive material on the second electrode 220. In detail, a light-transmitting adhesive layer capable of transmitting light may be formed on the second electrode 220. For example, the adhesive layer 420 may include an optical transparent adhesive layer OCA.

The adhesive layer 420 may be disposed on a partial region of the optical conversion part 300. That is, the adhesive layer 420 may be disposed in an area smaller than that of the optical conversion part 300. Accordingly, a region where the adhesive layer 410 is not disposed and the optical conversion part 300 is exposed may be formed on the optical conversion part 300.

In detail, a size of a fourth length extending in a first direction of the adhesive layer 420 may be greater than a size of a third length extending in a first direction of the optical conversion part 300, and a size of a fourth width extending in a second direction of the adhesive layer 420 may be smaller than a size of a third width extending in a second direction of the optical conversion part 300.

Subsequently, referring to FIG. 17, the first substrate 110 and the second substrate 120 may be adhered. In detail, the second substrate 120 may be disposed on the optical conversion part 300, and the second substrate 120 and the optical conversion part 300 may be adhered through the adhesive layer 420 disposed under the second substrate 120.

Accordingly, the first substrate 110, the optical conversion part 300, and the second substrate 120 may be sequentially stacked in the thickness direction of the first substrate 110, the optical conversion part 300, and the second substrate 120.

In this case, since the second substrate 120 is disposed in a size smaller than the size of the resin layer 350, a plurality of partition parts 310 and accommodation parts 320 may be exposed in a region where the second substrate 120 is not disposed on the optical conversion part 300.

In detail, since the size of the second width extending in the second direction of the second substrate 120 is smaller than the size of the third width extending in the second direction of the resin layer 350, the plurality of partition walls 310 and the accommodation part 320 may be exposed in an end region of at least one of one end and the other end facing in a width direction of the resin layer 350.

Subsequently, an optical conversion material 380 may be injected between the partition parts 310, that is, the accommodation parts 320. In detail, an optical conversion material in which light absorbing particles such as carbon black are dispersed in an electrolyte solvent including a paraffinic solvent and the like may be injected between the partition parts, that is, the accommodation parts 320.

For example, after disposing a dam extending in a longitudinal direction of the optical conversion part 300 on the accommodation part and the partition part of the optical conversion part 300 on which the second substrate 120 is not disposed, the electrolyte solvent may be injected into the accommodation part 320 by a capillary injection method between the dam and a side surface of the optical conversion part 300.

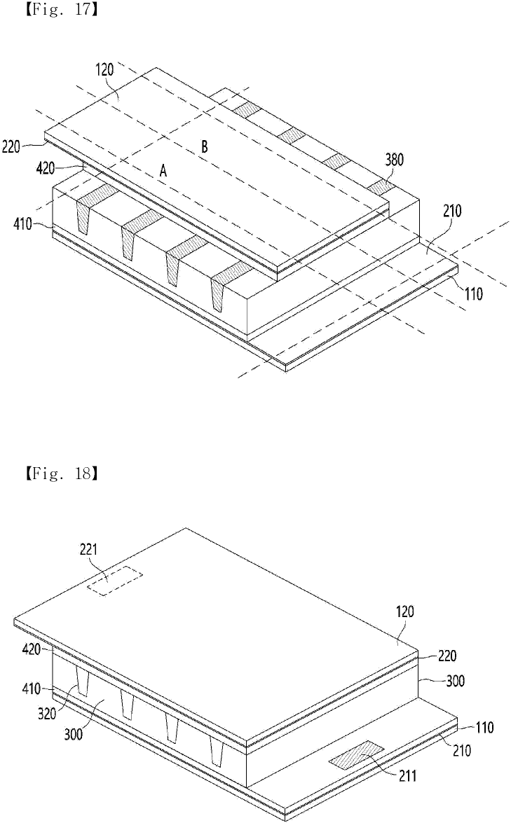

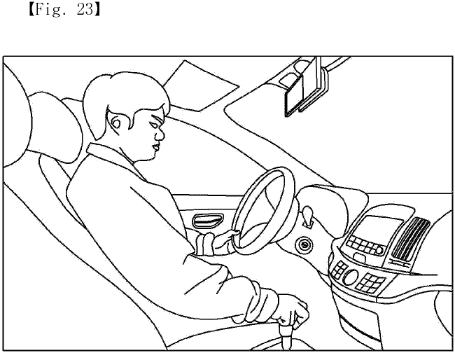

Subsequently, referring to FIG. 18, one optical path control member may be manufactured by cutting the optical conversion part 300. In detail, the optical conversion part 300 may be cut in a longitudinal direction of the optical conversion part 300. That is, the optical conversion part 300, the buffer layer 410 under the optical conversion part 300, the first electrode 210, and the first substrate 110 may be cut along the dotted line shown in FIG. 22. A plurality of optical path control members A and B may be formed by the cutting process, and FIG. 23 is a view showing one of the plurality of optical path control members.

In detail, the optical conversion part 300 may be cut so that side surfaces of the first substrate 110, the second substrate 120, and the optical conversion part 300 in the width direction may be disposed on the same plane.

Accordingly, both ends of the second substrate 120, the second electrode 220, or the adhesive layer 420 in the second direction and both ends of the optical conversion part 300 in the second direction may be disposed on the same plane.

That is, the both ends of the adhesive layer 420 in the second direction and the both ends of the optical conversion part 300 in the second direction may be connected to each other.

Alternatively, the both ends of the second substrate 120, the second electrode 220, or the adhesive layer 420 in the second direction may be disposed more outside than the both ends of the optical conversion part 300 in the second direction according to an error during the process.

Subsequently, the buffer layer 410 disposed on the first substrate 110 and/or the adhesive layer 420 disposed under the second substrate 120 may be partially removed to form a connection portion in which the electrode is exposed. In detail, when the buffer layer 410 is disposed on the first electrode where the optical conversion part 300 is not disposed on an upper surface of the first substrate 110, a first connection portion 211 may be formed on the first substrate 110 by removing a part of the first buffer layer 410 to expose the first electrode 210 or by not disposing the buffer layer 410 on the first electrode on which the optical conversion part 300 is not disposed from the beginning. In addition, when the adhesive layer 420 is disposed on the second electrode where the optical conversion part 300 is not disposed on a lower surface of the second substrate 120, a second connection portion 221 may be formed under the second substrate 120 by removing a part of the adhesive layer 420 or by not disposing the adhesive layer on the second electrode on which the optical conversion part 300 is not disposed during the adhesive process.

A printed circuit board or a flexible printed circuit board may be connected to the connection portions through an anisotropic conductive film (ACF) or the like, and the printed circuit board may be connected to an external power source to apply a voltage to the optical path control member.

Hereinafter, referring to FIGS. 19 to 23, a display device to which an optical path control member according to an embodiment is applied will be described.

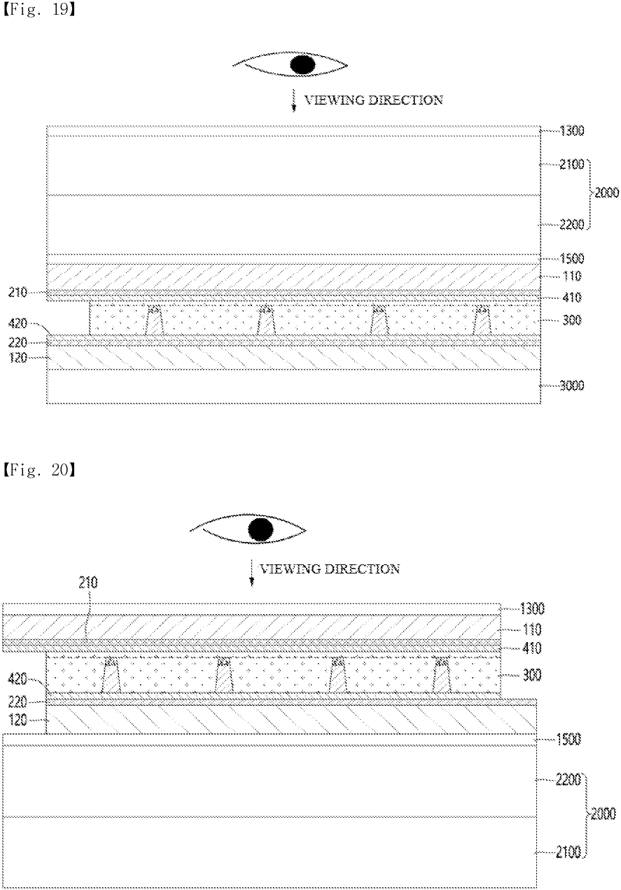

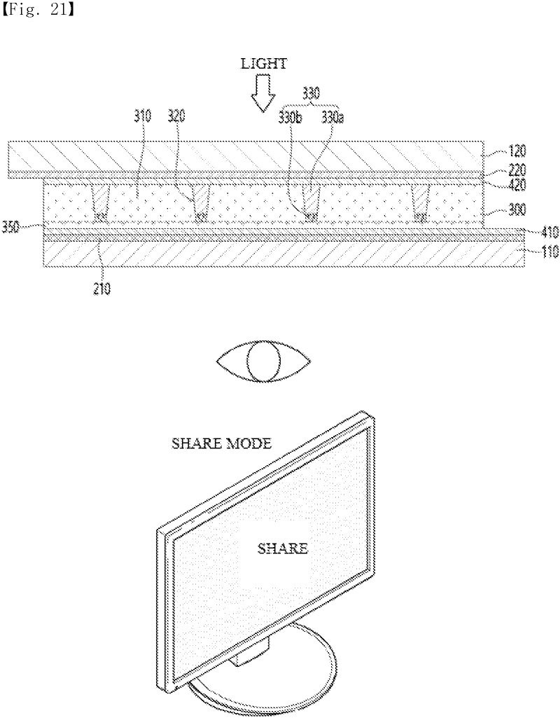

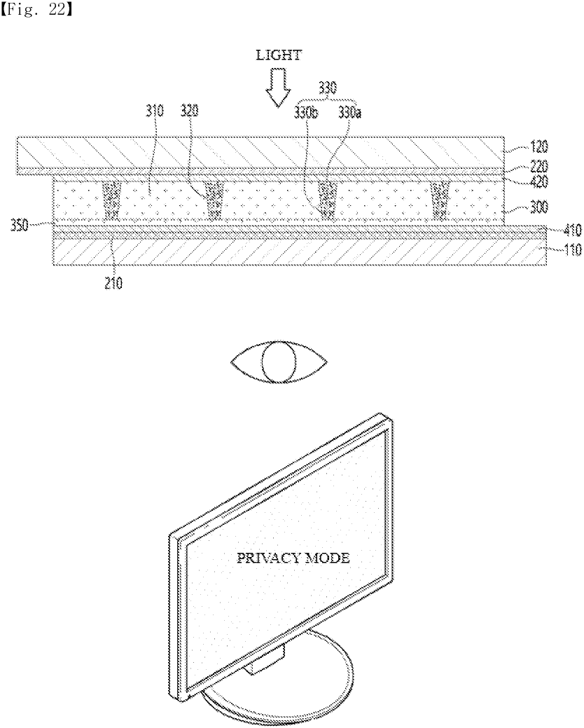

Referring to FIGS. 19 and 20, an optical path control member 1000 according to an embodiment may be disposed on or under a display panel 2000.

The display panel 2000 and the optical path control member 1000 may be disposed to be adhered to each other. For example, the display panel 2000 and the optical path control member 1000 may be adhered to each other via an adhesive layer 1500. The adhesive layer 1500 may be transparent. For example, the adhesive layer 1500 may include an adhesive or an adhesive layer including an optical transparent adhesive material.

The adhesive layer 1500 may include a release film. In detail, when adhering the optical path control member and the display panel, the optical path control member and the display panel may be adhered after the release film is removed.

Meanwhile, referring to FIGS. 19 and 20, one end or one end and the other end of the optical path control member may protrude, and the optical conversion part may not be disposed at the protruding portion. The protrusion region is an electrode connection portion in which the first electrode 210 and the second electrode 220 are exposed, and may connect an external printed circuit board and the optical path control member through the electrode connection portion.

The display panel 2000 may include a first’ substrate 2100 and a second’ substrate 2200. When the display panel 2000 is a liquid crystal display panel, the optical path control member may be formed under the liquid crystal panel. That is, when a surface viewed by the user in the liquid crystal panel is defined as an upper portion of the liquid crystal panel, the optical path control member may be disposed under the liquid crystal panel. The display panel 2000 may be formed in a structure in which the first’ substrate 2100 including a thin film transistor (TFT) and a pixel electrode and the second’ substrate 2200 including color filter layers are bonded to each other with a liquid crystal layer interposed therebetween.

In addition, the display panel 2000 may be a liquid crystal display panel of a color filter on transistor (COT) structure in which a thin film transistor, a color filter, and a black electrolyte are formed at the first’ substrate 2100 and the second’ substrate 2200 is bonded to the first’ substrate 2100 with the liquid crystal layer interposed therebetween. That is, a thin film transistor may be formed on the first’ substrate 2100, a protective film may be formed on the thin film transistor, and a color filter layer may be formed on the protective film. In addition, a pixel electrode in contact with the thin film transistor may be formed on the first’ substrate 2100. At this point, in order to improve an aperture ratio and simplify a masking process, the black electrolyte may be omitted, and a common electrode may be formed to function as the black electrolyte.

In addition, when the display panel 2000 is the liquid crystal display panel, the display device may further include a backlight unit 3000 providing light from a rear surface of the display panel 2000.

That is, as shown in FIG. 19, the optical path control member may be disposed under the liquid crystal panel and on the backlight unit 3000, and the optical path control member may be disposed between the backlight unit 3000 and the display panel 2000.

Alternatively, as shown in FIG. 20, when the display panel 2000 is an organic light emitting diode panel, the optical path control member may be formed on the organic light emitting diode panel. That is, when the surface viewed by the user in the organic light emitting diode panel is defined as an upper portion of the organic light emitting diode panel, the optical path control member may be disposed on the organic light emitting diode panel. The display panel 2000 may include a self-luminous element that does not require a separate light source. In the display panel 2000, a thin film transistor may be formed on the first’ substrate 2100, and an organic light emitting element in contact with the thin film transistor may be formed. The organic light emitting element may include an anode, a cathode, and an organic light emitting layer formed between the anode and the cathode. In addition, the second’ substrate 2200 configured to function as an encapsulation substrate for encapsulation may be further included on the organic light emitting element.

That is, light emitted from the display panel 2000 or the backlight unit 3000 may move from the second substrate 120 toward the first substrate 110 of the optical path control member.

In addition, although not shown in drawings, a polarizing plate may be further disposed between the optical path control member 1000 and the display panel 2000. The polarizing plate may be a linear polarizing plate or an external light reflection preventive polarizing plate. For example, when the display panel 2000 is a liquid crystal display panel, the polarizing plate may be the linear polarizing plate. Further, when the display panel 2000 is the organic light emitting diode panel, the polarizing plate may be the external light reflection preventing polarizing plate.

In addition, an additional functional layer 1300 such as an anti-reflection layer, an anti-glare, or the like may be further disposed on the optical path control member 1000. In detail, the functional layer 1300 may be adhered to one surface of the first substrate 110 of the optical path control member. Although not shown in drawings, the functional layer 1300 may be adhered to the first substrate 110 of the optical path control member via an adhesive layer. In addition, a release film for protecting the functional layer may be further disposed on the functional layer 1300.

Further, a touch panel may be further disposed between the display panel and the optical path control member.

It is shown in the drawings that the optical path control member is disposed at an upper portion of the display panel, but the embodiment is not limited thereto, and the optical path control member may be disposed at various positions such as a position in which light is adjustable, that is, a lower portion of the display panel, or between a second substrate and a first substrate of the display panel, or the like.

In addition, it is shown in the drawings that the optical conversion part of the optical path control member according to the embodiment is in a direction parallel or perpendicular to an outer surface of the second substrate, but the optical conversion part is formed to be inclined at a predetermined angle from the outer surface of the second substrate. Through this, a moire phenomenon occurring between the display panel and the optical path control member may be reduced.

Referring to FIGS. 21 to 23, an optical path control member according to an embodiment may be applied to various display devices.

Referring to FIGS. 21 to 23, the optical path control member according to the embodiment may be applied to a display device that displays a display.

For example, when power is applied to the optical path control member as shown in FIG. 21, the accommodation part functions as the light transmitting part, so that the display device may be driven in the share mode, and when power is not applied to the optical path control member as shown in FIG. 22, the accommodation part functions as the light blocking part, so that the display device may be driven in the privacy mode.

Accordingly, a user may easily drive the display device in a privacy mode or a normal mode according to application of power.

Light emitted from the backlight unit or the self-luminous element may move from the first substrate toward the second substrate. Alternatively, the light emitted from the backlight unit or the self-luminous element may also move from the second substrate toward the first substrate.

In addition, referring to FIG. 23, the display device to which the optical path control member according to the embodiment is applied may also be applied inside a vehicle.

For example, the display device including the optical path control member according to the embodiment may display a video confirming information of the vehicle and a movement route of the vehicle. The display device may be disposed between a driver seat and a passenger seat of the vehicle.

In addition, the optical path control member according to the embodiment may be applied to a dashboard that displays a speed, an engine, an alarm signal, and the like of the vehicle.

Further, the optical path control member according to the embodiment may be applied to a front glass (FG) of the vehicle or right and left window glasses.

The characteristics, structures, effects, and the like described in the above-described embodiments are included in at least one embodiment of the present invention, but are not limited to only one embodiment. Furthermore, the characteristic, structure, and effect illustrated in each embodiment may be combined or modified for other embodiments by a person skilled in the art. Accordingly, it is to be understood that such combination and modification are included in the scope of the present invention.

In addition, embodiments are mostly described above, but the embodiments are merely examples and do not limit the present invention, and a person skilled in the art may appreciate that several variations and applications not presented above may be made without departing from the essential characteristic of embodiments. For example, each component specifically shown in the embodiments may be modified and implemented. In addition, it should be construed that differences related to such a variation and such an application are included in the scope of the present invention defined in the following claims.

1-10. (canceled)

11. An optical path control member comprising:
a first substrate;
a first electrode disposed on the first substrate;
an optical conversion part disposed on the first electrode;
a second substrate disposed on the first substrate;
a second electrode disposed under the second substrate; and
an adhesive layer disposed between the optical conversion part and the second electrode,
wherein the optical conversion part includes a partition part and an accommodation part alternately disposed,
the accommodation part includes a dispersion liquid and optical conversion particles,
the accommodation part has a light transmittance that changes according to application of voltage, and
the dispersion liquid includes a solvent having a permittivity (ε) of 10 or less.

12. The optical path control member of claim 11, wherein the dispersion liquid includes a solvent having a permittivity (ε) of 5 or less.

13. The optical path control member of claim 11, wherein the dispersion liquid includes a solvent having a permittivity (ε) of 3 or less.

14. The optical path control member of claim 11, wherein the dispersion liquid includes a solvent having a permittivity (ε) greater than 2.1 to 3 or less.

15. The optical path control member of claim 11, wherein a driving speed measured by 85% reach time defined by Equation 1 below is less than six seconds
$$\text{85\% reach time (sec) = (maximum luminance - minimum luminance)*0} \text{.85} \text{.}$$
.

16. The optical path control member of claim 11, wherein the dispersion liquid includes one or more solvents.

17. The optical path control member of claim 14, wherein the dispersion liquid includes a polar solvent.

18. The optical path control member of claim 17, wherein the dispersion liquid further includes a non-polar solvent.

19. The optical path control member of claim 14, wherein the polar solvent includes a solvent having a dielectric constant of 10 or less.

20. The optical path control member of claim 11, wherein the dispersion liquid includes a mixture of solvents having mutually different permittivity.

21. The optical path control member of claim 11, wherein the dispersion liquid includes a solvent in which Isopar M and propylene glycol phenyl ether are mixed.

22. The optical path control member of claim 11, wherein the dispersion liquid includes a solvent in which Isopar M and 1-heptanol are mixed.

23. The optical path control member of claim 11, wherein the dispersion liquid includes a solvent in which Isopar M and liquid crystal are mixed.

24. The optical path control member of claim 11, wherein the first substrate and the second substrate are alternately disposed.

25. The optical path control member of claim 24, wherein the first substrate protrudes in one direction in the first direction, and
the second substrate protrudes in the other direction in the first direction.

26. The optical path control member of claim 11, wherein the optical conversion particles include carbon black particles.

27. The optical path control member of claim 11, wherein a size of the optical conversion part is smaller than that of at least one of the first substrate and the second substrate.

28. A display device comprising:
a display panel; and
the optical path control member according to claim 11 disposed on the display panel.
